(19) United States
(12) Patent Application Publication
(10) Pub. No.: US 2002/0061038 A1
(43) Pub. Date: May 23, 2002

(54) Method of producing semiconductor laser module and semiconductor laser module

(75) Inventors: Yoshiki Higashide, Curitiba (BR); Takeshi Aikiyo, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: The Furukawa Electric Co., Ltd., Chiyoda-ku (JP)

(21) Appl. No.: 09/965,862

(22) Filed: Oct. 1, 2001

(30) Foreign Application Priority Data
Nov. 22, 2000 (JP) 2000-355816

(51) Int. Cl. H01S 5/068

(52) U.S. Cl. 372/29.021

(57) ABSTRACT

A method of producing a semiconductor laser module, and a semiconductor laser module including a semiconductor laser element having a front facet to emit output light and a rear facet to emit monitor light, an optical fiber on which the output light is incident, a light receiving element receiving the monitor light emitted from the rear facet, and a substrate for supporting the semiconductor laser element and the light receiving element. The method of producing the semiconductor laser module comprises a step of receiving the monitor light output from the semiconductor laser element by the light receiving element, and adjusting the position of the light receiving element with respect to the semiconductor laser element based on an amount of received light at the light receiving element, and a step of fixing the light receiving element to a substrate through a supporting member.

### FIELD OF THE INVENTION

The present invention relates to a method of producing a semiconductor laser module and a semiconductor laser module produced by this method.

### BACKGROUND OF THE INVENTION

In a semiconductor laser module used as a light source for optical communication, a focussing lens is disposed between the front facet of a semiconductor laser element from which output light is emitted and an optical fiber, and a light receiving element that detects the output light for monitoring is disposed on the rear facet side of a semiconductor laser element from which the monitor light is emitted (see, for example, Japanese Unexamined Patent Publication No. Hei 6-318762).

In producing the above-mentioned semiconductor laser module, the output light of the semiconductor laser element is incident on an optical fiber, wherein the positions of the semiconductor laser element, the focussing lens and optical fiber are adjusted so that the coupling efficiency is maximized.

In the above-mentioned semiconductor laser module, for the purpose of performing a stable optical communication, it is important to maintain the power of the output light of the semiconductor laser element in a stable state. Thus, in the above-mentioned semiconductor laser module, the power of the output light is monitored by measuring the monitor light using a light receiving element as described above.

In a method of producing a typical semiconductor laser module, prior to placing and fixing the base in a package, a semiconductor laser element and a monitor light receiving element are fixed to the base.

Conventionally, a monitor light receiving element is appropriately positioned on the base without wiring for signal read-out, before being soldered on the base through a chip carrier.

Therefore, an amount of received light at the light receiving element is not known until the light emitted from the semiconductor laser element is received by the light receiving element after a base, which is mounted with the semiconductor laser element and the light receiving element, is fixed in the package, and wiring is provided therefor.

The light receiving element has an optimum dynamic range. If light is out of the range, the power variations in the monitor light output from the semiconductor laser element cannot be measured accurately.

In such a case, the optical output from the semiconductor laser element cannot be controlled precisely by the APC (Auto Power Control).

Thus, a semiconductor laser module having no suitable amount of received light at the light receiving element cannot be used for a desired use, and such a module is sometimes discarded.

### SUMMARY OF THE INVENTION

An object of the present invention is to provide a method of producing a semiconductor laser module capable of measuring monitor light accurately, and the semiconductor laser module.

To attain the above-mentioned object in the present invention, there is provided a method of producing a semiconductor laser module including a semiconductor laser element having a front facet to emit output light and a rear facet to emit monitor light, an optical fiber on which the output light is incident, a light receiving element, receiving the monitor light emitted from the rear facet, and a substrate for supporting the semiconductor laser element and the light receiving element, the method comprising a step A of receiving the monitor light output from the semiconductor laser element by the light receiving element, and adjusting the position of the light receiving element with respect to the semiconductor laser element based on an amount of received light at the light receiving element, and a step B of fixing the light receiving element to the substrate through a supporting member.

Further, to attain the above-mentioned object in the present invention, in a semiconductor laser module including a semiconductor laser element having a front facet emitting output light therefrom and a rear facet emitting monitor light therefrom, an optical fiber on which the output light is incident, a light receiving element receiving the monitor light emitted from the rear facet, and a substrate for supporting the semiconductor laser element and the light receiving element, the light receiving element is fixed to the substrate through a supporting member having a first holding member to fix the light receiving element thereon and a second holding member to adjust the position of the first holding member in the direction of the optical axis of the monitor light and capable of fixing the first holding member.

According to the present invention, a method of producing a semiconductor laser module, and a semiconductor laser module can be provided, which are capable of adjusting the position of a light receiving element with respect to a semiconductor laser element thereby to measure monitor light accurately.

The above and other objects, features and advantages of the present invention will become more apparently from the following descriptions based on the accompanying drawings.

### BRIEF DESCRIPTION OF THE DRAWINGS

FIG. 1 is a front view, in cross-section, of a semiconductor laser module according to the present invention;

FIG. 2 is a perspective view of a supporting member used in the semiconductor laser module of FIG. 1;

FIG. 3 is a perspective view showing a structure in which a carrier mounted with a semiconductor laser element, and a supporting member are fixed to a base disposed on a stage of a precise aligner, aligning equipment machine; and

FIG. 4 is a flow chart showing steps of fixing the carrier mounted with the semiconductor laser element, and the supporting member onto the base disposed on the stage of the precise aligner.

### DETAILED DESCRIPTION

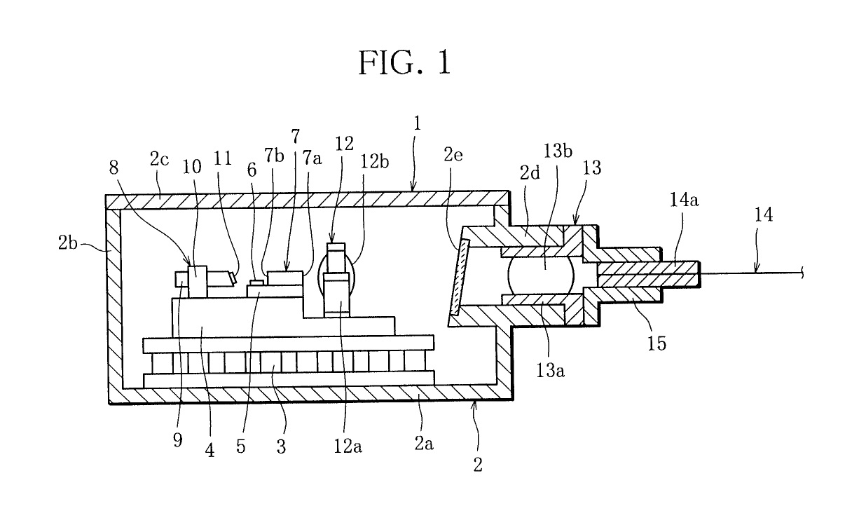

A method of producing a semiconductor laser module of the present invention and one embodiment according to the semiconductor laser module produced by this method, will now be described with reference to FIGS. 1 to 4.

As shown in FIG. 1, a semiconductor laser module 1 includes a package 2, a thermomodule 3, a base 4, a semiconductor laser element 7, a photodiode 11, a first lens unit 12, a second lens unit 13, and an optical fiber 14, and the like.

The package 2 has a bottom plate 2a, side walls 2b, a lid 2c attached to the upper portions of the side walls 2b. One of the side walls 2b is provided with an insertion cylinder 2d protruded inside and outside. To the inside of the insertion cylinder 2d is attached a hermetic glass plate 2e that seals the package 2 air tightly, and the glass plate 2e inclined at a predetermined angle. An anti-reflection coating is provided on the surface of the hermetic glass plate 2e.

The thermomodule 3, which is placed on the bottom plate 2a, is a module provided with Peltier elements for controlling the temperature of the semiconductor laser element 7. The semiconductor laser element 7 is controlled to a predetermined temperature by adjusting the operating current to the thermomodule 3 based on the temperature sensed at the thermistor 6 mounted on a carrier 5 to be described later.

The base 4 is a substrate which indirectly supports the semiconductor laser element 7 and the photodiode 11, and is placed on the thermomodule 3. The base 4 is provided with the carrier 5 to be described later, the supporting member 8 and the first lens unit 12.

The semiconductor laser element 7 is provided on the base 4 through the carrier 5 with a given separation to the first lens unit 12. Further, the semiconductor laser element 7 has a front facet 7a facing the first lens unit 12 and emitting the output light therefrom, and a rear facet 7b facing the photodiode 11 and emitting the monitor light therefrom. The semiconductor laser element 7 is optically coupled to the optical fiber 14 to be described later through a lens system comprising of the first lens unit 12 and the second lens unit 13.

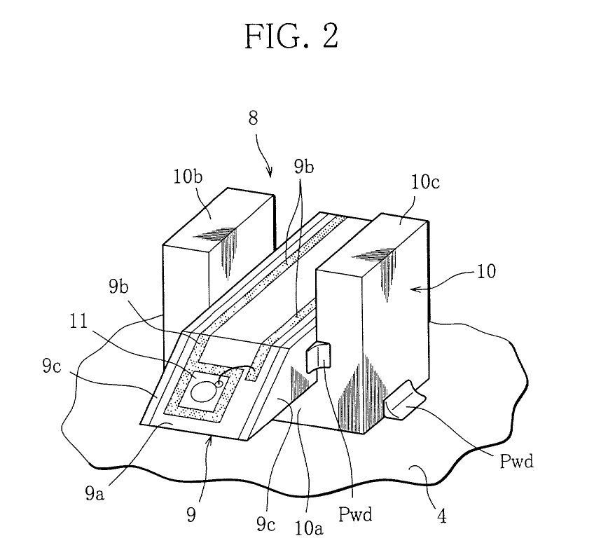

As shown in FIG. 1 and FIG. 2, the supporting member 8 includes a first holding member 9 and a second holding member 10. The first holding member 9 is formed of an insulator such as alumina in a rectangular column. An Au pattern 9b having a predetermined shape is formed on the inclined surface 9a and on the top surface continued thereto of the first holding member 9, and a side coating 9c of stainless steel is provided on both sides of the first holding member 9. The second holding member 10 is a stainless steel member formed in a concave shape, having a bottom portion 10a and side walls 10b, 10c standing from both side portions of the bottom portion 10a. The first holding member 9 is welded to both side walls 10b and 10c, respectively, of the second holding member 10. The second holding member 10 is welded to the base 4 at the bottom portion 10a. Thus, the first holding member 9 is fixed to the base 4 through the second holding member 10.

The photodiode 11 acts as a light receiving element that monitors the monitor light from the semiconductor laser element 7, and, as shown in FIG. 2, is disposed on the inclined surface 9a formed in the front portion of the first holding member 9.

As shown in FIG. 1, the first lens unit 12 is formed so that a collimator lens 12b is held by a lens holder 12a. The lens holder 12a is welded to the base 4.

The second lens unit 13 has a spherical lens 13b cut out in a cylindrical column which is held by a lens holder 13a. The lens holder 13a is fixed to the insertion cylinder 2d of the package 2.

To the distal end of the optical fiber 14 is attached a ferrule 14a. The ferrule 14a is adjusted to an optimum position by sliding it in the back and forth directions along the optical axis of the optical fiber 14 within an adjusting member 15, rotating it about the optical axis, and sliding the adjusting member 15 on the end surfaces of the second lens unit 13. Thereafter, the adjusting member 15 and the ferrule 14a are welded to the second lens unit 13 and the adjusting member 15, respectively.

The semiconductor laser module 1 constructed as explained above, is produced as follows.

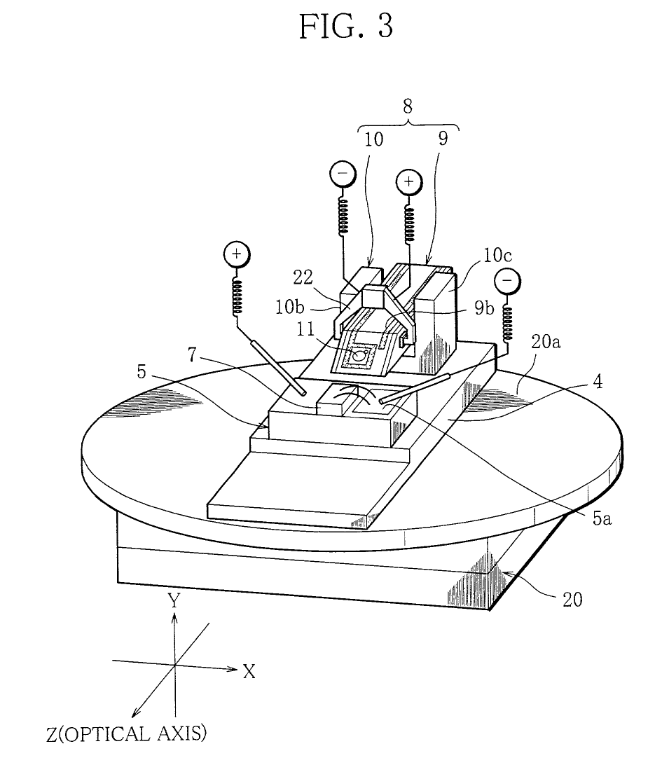

First, the base 4 is placed on the stage 20a of a precise aligner 20 shown in FIG. 3. Then, the stage 20a is moved in the three axial directions of X, Y, and Z axes orthogonal to each other, to accurately position the base 4 placed thereon with accuracy in unit of micron.

Then, the periphery of the carrier 5 is soldered to the base 4. The semiconductor laser element 7 is fixed beforehand by soldering onto the carrier 5 which has a circuit pattern 5a formed thereon being electrically connected to the semiconductor laser element 7 by wire bonding.

Then, the second holding member 10 is disposed adjacent to the carrier 5, as shown in FIG. 3. After that, the first holding member 9 is clamped by a chuck hand 22 from both sides thereof, and moved between both side walls 10b and 10c of the second holding member 10.

After that, as shown in FIG. 3, the semiconductor laser element 7 and the photodiode 11 are temporarily connected to the respective power suppliers (not shown).

Then, output light and monitor light are emitted from the semiconductor laser element 7, and the monitor light is received by the photodiode 11, so that the adjustment of position of the photodiode 11 with respect to the semiconductor laser element 7 is carried out based on the output.

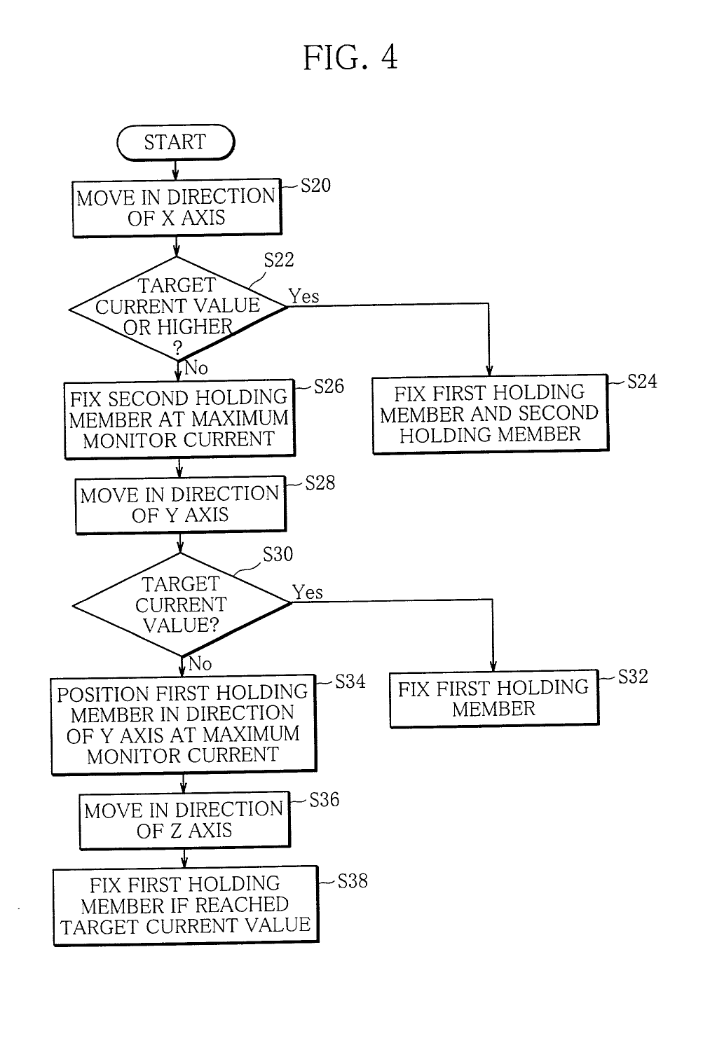

The positional adjustment method of the present invention will be described below in detail using a flow chart shown in FIG. 4.

First, the position of the first holding member 9 provided with the photodiode 11 is secured by the chuck hand 22 as shown in FIG. 3, and the stage 20a is moved in the direction of X axis while monitoring the monitor light emitted from the rear facet 7b of the semiconductor laser element 7 with the photodiode 11 (step S20). Meanwhile, the first holding member 9 is clamped with the chuck hand 22, and the position of the second holding member 10 is in the direction of X axis by the first holding member 9. Accordingly, the base 4 is moved in the direction of X axis.

Thus, the photodiode 11 is relatively moved in the direction of X axis with respect to the semiconductor laser element 7.

After this movement, it is determined whether or not the maximum value of the monitor current within the movement zone is above the target current value (step S22).

If the maximum value of the monitor current is above the target current value (judgement is positive (Yes)), the second holding member 10 is fixed to the base 4 at the position in the direction of X axis, and the first holding member 9 is fixed to the side walls 10b, 10c at the portion of the stainless steel layer 9c, by YAG welding (step S24).

On the other hand, if, in step 22, the maximum value of the monitor current is smaller than the target current value (judgement is negative (No)), the stage 20a is moved again along the X axis to fix the second holding member 10 to the base 4 at the position of a maximum monitor current (step S26). This welded point is shown as Pwd in FIG. 2.

Then, while monitor light to be monitored with the photodiode 11, the first holding member 9 supported between the side walls 10b and 10c of the second holding member 10 by the chuck hand 22 is moved along the Y axis (step S28).

Then, it is determined whether or not the maximum value of the monitor current within the movement zone was above the target current value (step S30).

If the maximum value of the monitor current reaches the target current value and the judgement is positive (Yes), the stainless steel layers 9c of the first holding member 9 are fixed to the side walls 10b and 10c of the second holding member 10 by YAG welding at that position (step S32).

On the other hand, if the judgement is negative (No) in step S30, the chuck hand 22 is stopped at a position that determines the position of the first holding member 9 in the direction of Y axis for the second holding member 10 so that the monitor current value becomes maximum (step S34).

After that, while monitor light to be monitored with the photodiode 11, the first holding member 9, positioned in the direction of Y axis, is moved with the chuck hand 22, so that it is brought near to the forward side of the semiconductor laser element 7 along the Z axis (step S36).

Then, if the maximum value of the monitor current reaches the target current value, the stainless steel layers 9c of the first holding member 9 are fixed to the side walls 10b and 10c of the second holding member 10 by YAG welding at that position (step S38).

As explained above, when the positioning of the semiconductor laser element 7 and the photodiode 11 are completed, the first lens unit 12 is fixed to the base 4 by YAG laser welding adjacent to the carrier 5. At this time, the lens holder 12a is fixed to the base 4 at a position where the output light (laser beam), emitted from the semiconductor laser element 7 and passed through the collimator lens 12b, becomes collimated.

Then, the lens holder 13a is inserted into the insertion cylinder 2d to be adjusted for its position in a plane perpendicular to the central axis of the insertion cylinder 2d, before the second lens unit 13 is fixed to the insertion cylinder 2d by welding.

After that, the ferrule 14a is inserted into the adjusting member 15, and the adjusting member 15 is abutted on the end portion of the lens holder 13a. In this state, the output light of the semiconductor laser light is incident on the optical fiber 14, and while monitoring the output light from the end portion of the optical fiber 14, the ferrule 14a is slid back and forth along the direction of, or it is rotated about an optical axis of the optical fiber 14, or the adjusting member 15 is slid on the end surface of the second lens unit 13, so that the ferrule 14a is adjusted to an optimum position with respect to the second lens unit 13, that gives a maximum coupling efficiency.

At this optimum position, the ferrule 14a is fixed to the adjusting member 15, and the adjusting member 15 is in turn fixed to the lens holder 13a, by welding, respectively.

Then, after the lid 2c is covered over the top portions of the side walls 2b and the production of the semiconductor laser module 1 is completed.

As described above, the method of producing the semiconductor laser module 1 according to the present invention and the semiconductor laser module 1 produced by this method can set the monitor current value to a desired target current value or to a maximum value since the position of the first holding member 9 mounted with the photodiode 11 is controlled along the directions of X axis and Y axis orthogonal to each other, both of which being perpendicular to the optical axis of the monitor light.

Therefore, according to the present invention the monitor light emitted from the semiconductor laser element 7 can be accurately measured with the photodiode 11, and the output light of the semiconductor laser element 7 can be properly controlled.

What is claimed is:

1. A method of producing a semiconductor laser module including a semiconductor laser element having a front facet to emit output light and a rear facet to emit monitor light, an optical fiber on which the output light is incident, a light receiving element, receiving the monitor light emitted from the rear facet, and a substrate for supporting the semiconductor laser element and the light receiving element, the method comprising:
step A of receiving the monitor light output from said semiconductor laser element by said light receiving element, and adjusting the position of the light receiving element with respect to the semiconductor laser element based on an amount of received light at the light receiving element, and
step B of fixing the light receiving element to said substrate through a supporting member.

2. The method of producing a semiconductor laser module according to claim 1,
wherein said step A comprises a substep of adjusting the position of said light receiving element along at least any one of either a direction of the optical axis of said monitor light, or a direction perpendicular to said optical axis.

3. The method of producing a semiconductor laser module according to claim 1,
wherein in said step A, said semiconductor laser element and said light receiving element are temporarily connected to an external circuit, such that said semiconductor laser element and said light receiving element are capable of emitting and detecting light, respectively.

4. The method of producing a semiconductor laser module according to claim 1,
wherein in said step B, said supporting member and said substrate are laser welded to each other.

5. A semiconductor laser module including a semiconductor laser element having a front facet emitting output light therefrom and a rear facet emitting monitor light therefrom, an optical fiber on which said output light is incident, a light receiving element receiving the monitor light emitted from said rear facet, and a substrate for supporting said semiconductor laser element and said light receiving element,
wherein said light receiving element is fixed to said substrate through a supporting member having a first holding member to fix said light receiving element thereon and a second holding member to adjust said position of said first holding member in the direction of the optical axis for said monitor light and capable of fixing said first holding member.

6. The semiconductor laser module according to claim 5,
wherein said first holding member is a rod-shaped body to an end of which said light receiving element is fixed, and said second holding member has a bottom portion fixed to said substrate and side walls which stands from both side portions of said bottom portion and fixed to said first holding member.
